(19) United States
(12) Patent Application Publication
(10) Pub. No.: US 2009/0085200 A1
(43) Pub. Date: Apr. 2, 2009

(54) LOW LOSS RADIO FREQUENCY SIGNAL COMMUNICATION WITHIN A PACKAGE, A BOARD AND/OR A WAVE GUIDE

(76) Inventor: Raviprakash Nagaraj, Tigard, OR (US)

Correspondence Address: INTEL/BSTZ;BLAKELY SOKOLOFF TAYLOR & ZAFMAN LLP, 1279 OAKMEAD PARKWAY, SUNNYVALE, CA, 94085-4040, US

(21) Appl. No.: 11/864,803

(22) Filed: Sep. 28, 2007

(51) Int. Cl. H01L 23/34

(52) U.S. Cl. 257/728; 257/E23.015

(57) ABSTRACT

In some embodiments an integrated circuit package includes a coaxial arrangement of one or more ground via surrounding a signal via. The one or more ground via and the signal via extend through the package to allow transmission of signals between an integrated circuit and a board. Other embodiments are described and claimed.

### TECHNICAL FIELD

The inventions generally relate to low loss radio frequency signal communication within a package, a board and/or a wave guide.

### BACKGROUND

As the computer industry focuses on more energy efficient circuits the energy consumed by interconnects on the system boards (and/or motherboards) is becoming a dominant factor in platform design. Wave guides are used in a variety of applications to carry radio frequency energy from one point to another. A wave guide is a transmission line that carries signals. Wave guide interconnects are being added to system boards (or motherboards) within computers to carry signals along the board.

### BRIEF DESCRIPTION OF THE DRAWINGS

The inventions will be understood more fully from the detailed description given below and from the accompanying drawings of some embodiments of the inventions which, however, should not be taken to limit the inventions to the specific embodiments described, but are for explanation and understanding only.

FIG. 1 illustrates a system according to some embodiments of the inventions.

### DETAILED DESCRIPTION

Some embodiments of the inventions relate to low loss radio frequency signal communication within a package, a board and/or a wave guide.

In some embodiments an integrated circuit package includes a coaxial arrangement of one or more ground pads surrounding a signal pad. The one or more ground pads and the signal pad connect to corresponding pads in the package and a corresponding signal via and ground via extend through the package to allow transmission of signals between an integrated circuit and a board.

In some embodiments an integrated circuit package includes a signal via extending through the package and one or more ground via surrounding the signal via and extending through the package. The one or more ground via and the signal via extend through the package to form a coaxial arrangement that allows transmission of signals.

In some embodiments a board includes a signal via extending through the board and one or more ground via surrounding the signal via and extending through the board. The one or more ground via and the signal via extend through the board to form a coaxial arrangement that allows transmission of signals.

In some embodiments an apparatus includes a wave guide and a signal via extending through the wave guide. One or more ground via surrounding the signal via and extending up to the wave guide. The one or more ground via and the signal via extend to the wave guide to form a coaxial arrangement that allows transmission of signals.

As the computer industry moves toward more energy efficient circuits, the energy consumed by the interconnect is becoming a dominant concern. A low power method of communicating information from one point in a circuit board to another is to use a micro-radio and a wave guide. According to some embodiments, a micro-radio and a wave guide may provide a substantial power advantage over other transmission techniques.

In some embodiments loss is minimized. This loss relates to communication of a signal from a radio on an integrated circuit (for example, on a silicon chip) through a package and into a wave guide on a system board. Other techniques for routing a signal from a silicon wafer through a package incurs large losses for a radio frequency (RF) signal and are therefore not advantageous. According to some embodiments, a virtual coaxial cable is established from a signal bump in a silicon chip through a package and into a wave guide on a system board.

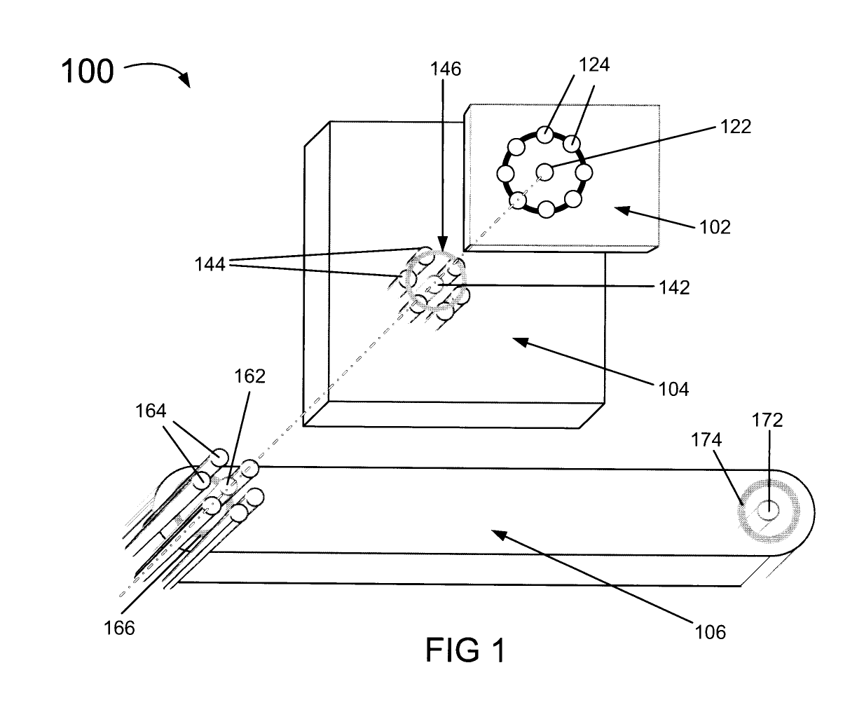

FIG. 1 illustrates a system 100 according to some embodiments. In some embodiments system 100 includes an integrated circuit (for example, a silicon chip) 102, a package 104, and a wave guide 106. In some embodiments the wave guide 106 is resident on and/or contained within a board such as, for example, a printed circuit board (PCB), a system board, and/or a motherboard, etc. In some embodiments the integrated circuit (IC) 102 is a wireless IC. In some embodiments the integrated circuit (IC) 102 is a radio IC. In some embodiments the IC 102 is a micro-radio. The IC 102 includes a signal bump 122 and at least one ground bump 124 surrounding the signal bump 122. In FIG. 1 eight ground bumps 124 are illustrated. However, any number of ground bumps 124 may be included according to some embodiments. Package 104 includes a signal via 142 and at least one ground via 144 surrounding the signal via 142. In FIG. 1 six ground vias 144 are illustrated. However, any number of ground vias 144 may be included according to some embodiments. Wave guide 106 includes a signal via 162 and at least one ground via 164 surrounding the signal via 162. The vias extend up to the wave guide 106. In FIG. 1, six ground vias 164 are illustrated. However, any number of ground vias 164 may be included according to some embodiments. Ground vias 164 may be excluded in the direction of the wave travel in the wave guide (towards via 172). Wave guide 106 also includes a signal via 172 which may be electromagnetically coupled to signal via 162. Guard rings 166 and 174 may surround the signal vias 162 and 172 respectively.

In some embodiments signal loss may be reduced while transmitting a signal from a radio on the IC 102, through the package 104, and through the wave guide 106. A virtual coaxial cable is established from the signal bump 122 in the IC 102 through the package 104 and into the wave guide 106.

In some embodiments a virtual coaxial cable is created within a stack containing an IC 102, a package 104, and/or a wave guide 106. The signal bump 122 on the IC 102 conveys a radio frequency signal, and is arranged so that the signal bump 122 lands on and/or is coupled with a pad on the package 104. A via-in-pad structure (for example, including signal via 142 and also in some embodiments ground vias 144) is used to convey this signal all the way down to the other side of the package 104 (for example, to the bottom side of the package in FIG. 1). This is accomplished with a minimum amount of signal discontinuity.

In some embodiments the signal bump 122 on the IC that conveys the radio frequency signal is surrounded by one or more of the ground bumps 124. In some embodiments ground bumps 124 are coupled to an analog ground signal inside the IC 102. In some embodiments the ground bumps 124 are spaced a certain distance away from the radio signal conveyed on the signal bump 122 such that a correct electrical impedance is achieved to match an impedance of the wave guide 106. In some embodiments, such spacing allows vias 142 and/or 144 to traverse the height of the package 104 with no discontinuity such that the vias 142 and/or 144 end in package balls on the other side or surface of the package 104 (for example, the bottom side or surface of package 104 in FIG. 1).

In some embodiments ground bumps 124 land on a pattern of pads connected together to form a ring 146 on the top surface of package 104. In some embodiments the ground vias 144 are drilled through the package 104 all around the ring 146, and the ground vias 144 connect to ground planes within inner layers of the package 104. In some embodiments the ground vias 144 form a ground shield on all sides of the radio signal passing through the signal via 142. In some embodiments, on the other side (or surface) of the package 104 (at the bottom in FIG. 1) a package ball is provided in the center to carry the radio frequency signal. Package balls form a ring around the package ball to provide a coaxial shield.

In some embodiments ground vias 144 land on a pattern of pads connected together to form a ring 166 on the top surface of wave guide 106. In some embodiments the ground vias 164 extend up to the wave guide 106 all around the ring 166. In some embodiments the ground vias 164 form a ground shield on all sides of the radio signal passing through the signal via 162. In some embodiments, the signal may be transmitted through the wave guide 106 to the signal via 172, which may be coaxially shielded by the guard ring 174. In some embodiments signal via 172 transmits the signal from the wave guide 106 to another IC, for example.

In some embodiments a coaxial cable arrangement is provided between packages and boards (for example, printed circuit boards). In some embodiments the impedance offered to the radio frequency wave is uniform from chip to chip, resulting in low distortion and low loss. In some embodiments a coaxial cable is provided within a package. In some embodiments a coaxial cable is provided within a board. In some embodiments a coaxial cable is provided within a wave guide (where the wave guide is included, for example, in a board).

Although some embodiments have been described in reference to particular implementations, other implementations are possible according to some embodiments. Additionally, the arrangement and/or order of circuit elements or other features illustrated in the drawings and/or described herein need not be arranged in the particular way illustrated and described. Many other arrangements are possible according to some embodiments.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

In the description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other electromagnetically.

An algorithm is here, and generally, considered to be a self-consistent sequence of acts or operations leading to a desired result. These include physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers or the like. It should be understood, however, that all of these and similar terms are to be associated with the appropriate physical quantities and are merely convenient labels applied to these quantities.

Some embodiments may be implemented in one or a combination of hardware, firmware, and software. Some embodiments may also be implemented as instructions stored on a machine-readable medium, which may be read and executed by a computing platform to perform the operations described herein. A machine-readable medium may include any mechanism for storing or transmitting information in a form readable by a machine (e.g., a computer). For example, a machine-readable medium may include read only memory (ROM); random access memory (RAM); magnetic disk storage media; optical storage media; flash memory devices; electrical, optical, acoustical or other form of propagated signals (e.g., carrier waves, infrared signals, digital signals, the interfaces that transmit and/or receive signals, etc.), and others.

An embodiment is an implementation or example of the inventions. Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the inventions. The various appearances “an embodiment,” “one embodiment,” or “some embodiments” are not necessarily all referring to the same embodiments.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

Although flow diagrams and/or state diagrams may have been used herein to describe embodiments, the inventions are not limited to those diagrams or to corresponding descriptions herein. For example, flow need not move through each illustrated box or state or in exactly the same order as illustrated and described herein.

The inventions are not restricted to the particular details listed herein. Indeed, those skilled in the art having the benefit of this disclosure will appreciate that many other variations from the foregoing description and drawings may be made within the scope of the present inventions. Accordingly, it is the following claims including any amendments thereto that define the scope of the inventions.

What is claimed is:

1. An apparatus comprising:
a board;
an integrated circuit;
an integrated circuit package including a coaxial arrangement of one or more ground via surrounding a signal via, wherein the one or more ground via and the signal via extend through the package to allow transmission of signals between the integrated circuit and the board.

2. The apparatus of claim 1, wherein the integrated circuit is a wireless integrated circuit that transmits radio frequency signals through the signal via in the package.

3. The apparatus of claim 1, wherein the board includes a wave guide, and wherein the one or more ground via and the signal via extend through the package to allow transmission between the integrated circuit and the wave guide.

4. The apparatus of claim 3, wherein the wave guide includes a coaxial arrangement up to an edge of the wave guide of one or more ground via surrounding a signal via to further allow transmission of the signals to the wave guide.

5. The apparatus of claim 4, further comprising a second integrated circuit, wherein the coaxial arrangement up to the wave guide and the coaxial arrangement of the package allow transmission of signals between the integrated circuit and the second integrated circuit.

6. The apparatus of claim 1, wherein the ground vias form a ring on a surface of the package.

7. The apparatus of claim 1, wherein the vias form a coaxial shield in the package.

8. An integrated circuit package comprising:
a signal via extending through the package; and
one or more ground via surrounding the signal via and extending through the package;
wherein the one or more ground via and the signal via extend through the package to form a coaxial arrangement that allows transmission of signals.

9. The package of claim 8, wherein the signal via transmits radio frequency signals through the package.

10. The package of claim 8, wherein the one or more ground via and the signal via extend through the package to allow transmission between an integrated circuit and a wave guide.

11. The package of claim 6, wherein the ground vias form a ring on a surface of the package.

12. The package of claim 6, wherein the vias form a coaxial shield in the package.

13. A board comprising:
a signal via extending through the board; and
one or more ground via surrounding the signal via and extending through the board;
wherein the one or more ground via and the signal via extend through the board to form a coaxial arrangement that allows transmission of signals.

14. The board of claim 13, wherein the coaxial arrangement allows transmission of wireless signals through the signal via in the board.

15. The board of claim 13, wherein the coaxial arrangement allows transmission of signals between two integrated circuits.

16. The board of claim 13, wherein the coaxial arrangement allows transmission of signals through an integrated circuit package.

17. The board of claim 13, wherein the ground vias form a ring on a surface of the board.

18. The board of claim 13, wherein the vias form a coaxial shield in the board.

19. An apparatus comprising:
a signal via extending through the wave guide; and
one or more ground via surrounding the signal via and extending to the wave guide;
wherein the one or more ground via and the signal via extend to the wave guide to form a coaxial arrangement that allows transmission of signals.

20. The wave guide of claim 19, wherein the coaxial arrangement allows transmission of radio frequency signals through the signal via in the wave guide.

21. The apparatus of claim 19, wherein the coaxial arrangement allows transmission of signals between two integrated circuits.

22. The apparatus of claim 19, wherein the coaxial arrangement allows transmission of signals through an integrated circuit package.

23. The apparatus of claim 19, wherein the ground vias form a ring on a surface of the wave guide.

24. The apparatus of claim 19, wherein the vias form a coaxial shield in the wave guide.
